(19) United States
(12) Patent Application Publication
(10) Pub. No.: US 2018/0269078 A1
(43) Pub. Date: Sep. 20, 2018

(54) SUBSTRATE TREATMENT DEVICE AND SUBSTRATE TREATMENT METHOD

(71) Applicant: JUSUNG ENGINEERING CO., LTD., Gwangju-si, Gyeonggi-do (KR)

(72) Inventors: Min Ho CHEON, Gwangju-si, Gyeonggi-do (KR); Jin Hyuk YOO, Gwangju-si, Gyeonggi-do (KR); Chul-Joo HWANG, Gwangju-si, Gyeonggi-do (KR)

(21) Appl. No.: 15/753,967

(22) PCT Filed: Aug. 19, 2016
(86) PCT No.: PCT/KR2016/009179

§ 371 Date: Feb. 20, 2018

(30) Foreign Application Priority Data
Aug. 20, 2015 (KR) 10-2015-0117464

(51) Int. Cl. H01L 21/67; H01L 21/687; H01L 21/02; H01L 21/311; H01J 37/32; C23C 16/509

(52) U.S. Cl. CPC H01L 21/67017; H01L 21/68771; H01L 21/67069; H01L 21/02274; H01L 21/31116; H01J 37/32183; H01J 37/32743; H01J 37/32715; C23C 16/509; H01J 2237/3321; H01J 37/32449

(57) ABSTRACT

A substrate treatment device according to an embodiment of the present invention may include a process chamber, a substrate supporting part installed in the process chamber to support a plurality of substrates and rotating in a certain direction, a chamber lid covering a top of the process chamber to be opposite to the substrate supporting part, and a gas distribution unit installed in the chamber lid to spatially separate different first and second gases and distribute the spatially separated first and second gases to the plurality of substrates. The substrate supporting part may include a first disk provided to be rotatable and at least one second disk disposed on the first disk to rotate and revolve about a center of the first disk according to the first disk rotating, the plurality of substrates being disposed on the at least one second disk.

### TECHNICAL FIELD

The present invention relates to a substrate treatment device and a substrate treatment method.

### BACKGROUND ART

Details described herein merely provide background information about embodiments and do not configure the related art.

Generally, a thin-film layer, a thin-film circuit pattern, or an optical pattern should be formed on a substrate surface for manufacturing a solar cell, a semiconductor device, a flat panel display device, etc. To this end, a semiconductor manufacturing process is performed, and examples of the semiconductor manufacturing process include a thin film deposition process of depositing a thin film including a specific material on a substrate, a photo process of selectively exposing a portion of a thin film by using a photosensitive material, an etching process of removing a thin film corresponding to the selectively exposed portion to form a pattern, etc.

The semiconductor manufacturing process is performed inside a substrate treatment device which is designed based on an optimal environment for a corresponding process, and recently, substrate treatment devices for performing a deposition or etching process based on plasma are much used.

Examples of the substrate treatment devices based on plasma include plasma enhanced chemical vapor deposition (PECVD) apparatuses for forming a thin film by using plasma, plasma etching apparatuses for etching and patterning a thin film, etc.

FIG. 1 is a diagram for schematically describing a general substrate treatment device.

Referring to FIG. 1, a general substrate treatment device 10 includes a chamber 10, a plasma electrode 20, a susceptor 30, and a gas distribution means 40.

The chamber 10 provides a reaction space for a substrate processing process. In this case, one floor surface of the chamber 10 communicates with an exhaust port 12 for exhausting the reaction space.

The plasma electrode 20 is installed on the chamber 10 to seal the reaction space. One side of the plasma electrode 20 is electrically connected to a radio frequency (RF) power source 24 through a matching member 22. In this case, the RF power source 24 generates RF power and supplies the RF power to the plasma electrode 20.

Moreover, a center portion of the plasma electrode 20 communicates with a gas supply pipe 26 that supplies a source gas for the substrate processing process.

The matching member 22 is connected between the plasma electrode 20 and the RF power source 24 and matches a source impedance with a load impedance of the RF power supplied from the RF power source 24 to the plasma electrode 20.

The susceptor 30 is installed in the chamber 10 and supports a plurality of substrates W loaded from the outside. The susceptor 30 is an opposite electrode opposite to the plasma electrode 20 and is electrically grounded through an elevation shaft 32 that raises and lowers the susceptor 30.

The elevation shaft 32 is raised and lowered in an up and down direction by an elevation apparatus (not shown). At this time, the elevation shaft 32 is surrounded by bellows 34 that seal the elevation shaft 32 and a floor surface of the chamber 10.

The gas distribution means 40 is installed under the plasma electrode 20 to be opposite to the susceptor 30. In this case, a gas diffusion space 42 where a source gas supplied from the gas supply pipe 26 passing through the plasma electrode 20 is diffused is provided between the gas distribution means 40 and the plasma electrode 20. The gas distribution means 40 uniformly distributes the source gas to a whole portion of the reaction space through a plurality of gas distribution holes 44 communicating with the gas diffusion space 42.

The general substrate treatment device loads the substrate W onto the susceptor 30, distributes the source gas to the reaction space of the chamber 10, and supplies the RF power to the plasma electrode 20 to generate an electric field, whereby a thin film on the substrate W is formed by using plasma generated on the substrate W by the electric field.

However, in the general substrate treatment device, since the distribution space is the same as a plasma space, uniformity of a thin film material deposited on the substrate W is determined based on uniformity of a density of plasma generated in the reaction space, and for this reason, it is difficult to control quality of the thin film material.

### DISCLOSURE

### Technical Problem

Therefore, the present invention has been made in view of the above problems, and it is an object of the present invention to provide a substrate treatment device and a substrate treatment method, which spatially separate a source gas and a reactant gas distributed to a substrate, revolve and rotate each of a first disk and a second disk to increase the deposition uniformity of a thin film deposited on the substrate, facilitate the control of quality of the thin film, and minimize an accumulation thickness deposited in a chamber to reduce particles.

In addition to the aforesaid objects of the present invention, other features and advantages of the present invention will be described below, but will be clearly understood by those skilled in the art from descriptions below.

### Technical Solution

To accomplish the above-described objects, a substrate treatment device according to an embodiment of the present invention may include: a process chamber; a substrate supporting part installed in the process chamber to support a plurality of substrates, the substrate supporting part rotating in a certain direction; a chamber lid covering a top of the process chamber to be opposite to the substrate supporting part; and a gas distribution unit installed in the chamber lid to spatially separate different first and second gases and distribute the spatially separated first and second gases to the plurality of substrates, wherein the substrate supporting part may include: a first disk provided to be rotatable; and at least one second disk disposed on the first disk to rotate and revolve about a center of the first disk according to the first disk rotating, the plurality of substrates being disposed on the at least one second disk, and a rotation speed of the first disk may differ from a rotation speed of the second disk.

A ratio of the rotation speed of the first disk to the rotation speed of the second disk may be 1:0.1 or more and 1:less than 1.

The gas distribution unit may include: a first gas distribution module installed in the chamber lid to distribute the first gas supplied to a gas distribution space provided between a plurality of ground electrode members; and a second gas distribution module installed in the chamber lid and separated from the first gas distribution module, the second gas distribution module distributing the second gas supplied to the gas distribution space provided between the plurality of ground electrode members.

At least one of the first and second gas distribution modules may include a plasma electrode member disposed between the plurality of ground electrode members to generate plasma in the gas distribution space.

To accomplish the above-described objects, a substrate treatment device according to an embodiment of the present invention may include: a process chamber; a substrate supporting part installed in the process chamber to support a plurality of substrates, the substrate supporting part rotating in a certain direction; a chamber lid covering a top of the process chamber to be opposite to the substrate supporting part; and a gas distribution unit including a first gas distribution module installed in the chamber lid to overlap a first gas distribution area on the substrate supporting part, the first gas distribution module distributing a first gas to the first gas distribution area, and a second gas distribution module installed in the chamber lid to overlap a second gas distribution area spatially separated from the first gas distribution area, the second gas distribution module distributing a second gas to the second gas distribution area, wherein the substrate supporting part may include: a first disk provided to be rotatable; and at least one second disk disposed on the first disk to rotate and revolve about a center of the first disk according to the first disk rotating, the plurality of substrates being disposed on the at least one second disk, and the second gas distribution module may make the second gas plasmatic to distribute a plasmatic second gas according to a plasma power supplied to a plasma electrode member which is disposed alternately with a plurality of ground electrode members.

The first gas distribution module may distribute the first gas supplied to between the plurality of ground electrode members as-is, or may make the first gas plasmatic to distribute a plasmatic first gas according to the plasma power supplied to the plasma electrode member which is disposed alternately with the plurality of ground electrode members.

Each of the first and second gas distribution modules may be provided in plurality, and each of the plurality of second gas distribution modules may be disposed alternately with the plurality of first gas distribution modules.

The gas distribution unit may further include third and fourth gas distribution modules installed in the chamber lid and disposed between the first and second gas distribution modules to distribute a third gas to the plurality of substrates.

To accomplish the above-described objects, a substrate treatment device according to an embodiment of the present invention may include: a process chamber; a substrate supporting part installed in the process chamber to support a plurality of substrates, the substrate supporting part rotating in a certain direction; a chamber lid covering a top of the process chamber to be opposite to the substrate supporting part; and a gas distribution unit including a plurality of gas distribution modules arranged at certain intervals in the chamber lid, the plurality of gas distribution modules each including a gas distribution space provided between a plurality of ground electrode members, wherein at least one of the plurality of gas distribution modules may generate plasma in the gas distribution space according to a plasma power supplied to a plasma electrode member which is disposed alternately with a plurality of ground electrode members, and the substrate supporting part may include: a first disk provided to be rotatable; and at least one second disk disposed on the first disk to rotate and revolve about a center of the first disk according to the first disk rotating, the plurality of substrates being disposed on the at least one second disk.

To accomplish the above-described objects, a substrate treatment method according to an embodiment of the present invention may include: (A) arranging a plurality of substrates at certain intervals on a substrate supporting part installed in a process chamber; (B) rotating the substrate supporting part, on which the plurality of substrates are disposed, to rotate and revolve a second disk about a center axis of a first disk according to the first disk rotating; and (C) spatially separating different first and second gases and distributing the spatially separated first and second gases to the plurality of substrates by using each of first and second gas distribution modules which are arranged at certain intervals in a chamber lid covering a top of the process chamber to be opposite to the substrate supporting part, wherein in step (C), the first gas distribution module distributes the first gas, supplied to a gas distribution space between a plurality of ground electrode members, to the plurality of substrates, and the second gas distribution module distributing the second gas, supplied to the gas distribution space between the plurality of ground electrode members, to the plurality of substrates to be spatially separated from the first gas.

A ratio of a rotation speed of the first disk to a rotation speed of the second disk may be 1:0.1 or more and 1:less than 1.

Step (C) may simultaneously or sequentially perform a first gas distribution operation of distributing the first gas through the first gas distribution module and a second gas distribution operation of distributing the second gas through the second gas distribution module.

The first gas may be changed to a plasmatic first gas by plasma generated in a gas distribution space of the first gas distribution module, and the plasmatic first gas may be distributed to the plurality of substrates.

### Advantageous Effect

According to the technical solution, the substrate treatment device and the substrate treatment method according to the present invention spatially separate a source gas and a reactant gas by using a plurality of gas distribution modules which are spatially separated from each other and disposed on a substrate supporting part, and distribute the source gas and the reactant gas to the substrate, thereby increasing the deposition uniformity of a thin film deposited on each of substrates, facilitating the control of quality of the thin film, and minimizing an accumulation thickness deposited in a process chamber to reduce particles.

Moreover, by using a purge gas, the substrate treatment device and the substrate treatment method according to the present invention prevent reaction from being made between the source gas and the reactant gas in the middle of being distributed to the substrate, thereby further facilitating the control of uniformity of a thin film material and quality of the thin film material.

In an embodiment, since the second disk rotates without using a separate second disk rotation apparatus using air or a gas, a structure of the substrate treatment device is simplified, and an consumption amount of power and energy used in substrate processing is reduced.

Moreover, a product defect caused by a foreign material which is contained in air or a gas and is adsorbed onto a substrate such as a waver or the like is considerably reduced by using a rotation apparatus using air or a gas.

Moreover, shaking of a substrate loaded onto a top of the second disk, non-uniform deposition on the substrate, and etching are prevented by suppressing vibration and noise which occur when the second disk rotates.

Moreover, if constant ratios of speeds are differently maintained by differently setting a rotation speed of the first disk and a rotation speed of the second disk, it is easier to control uniformity of the thin film material and quality of the thin film material.

### DESCRIPTION OF DRAWINGS

FIG. 1 is a diagram for schematically describing a general substrate treatment device.

FIG. 2A is a diagram for schematically describing a substrate treatment device according to a first embodiment of the present invention.

FIG. 2B is a cross-sectional perspective view illustrating a substrate treatment device according to an embodiment of the present invention.

FIG. 3 is a cross-sectional view schematically illustrating a cross-sectional surface of a gas distribution module illustrated in FIG. 2A.

FIG. 4A is a diagram for describing a substrate treatment method using the above-described substrate treatment device according to the first embodiment of the present invention.

FIG. 4B is a waveform diagram for describing an operation sequence of first to fourth gas distribution modules illustrated in FIG. 4A.

FIGS. 5A to 5D are waveform diagrams for describing modification examples of a substrate treatment method using first to fourth gas distribution modules illustrated in FIG. 2.

FIG. 6 is a diagram for describing a modification embodiment of the substrate treatment device according to the first embodiment of the present invention.

FIG. 7 is a waveform diagram for describing an operation sequence of first to fourth gas distribution modules illustrated in FIG. 6.

FIG. 8 is a diagram schematically illustrating a substrate treatment device according to a second embodiment of the present invention.

FIG. 9 is a cross-sectional view schematically illustrating a cross-sectional surface of each of first and third gas distribution modules illustrated in FIG. 8.

FIG. 10 is a diagram for describing a substrate treatment method using the above-described substrate treatment device according to the second embodiment of the present invention.

FIG. 11 is a diagram schematically illustrating a substrate treatment device according to a third embodiment of the present invention.

FIG. 12 is a diagram for describing a substrate treatment method using the above-described substrate treatment device according to the third embodiment of the present invention.

FIG. 13 is a diagram schematically illustrating a substrate treatment device according to a fourth embodiment of the present invention.

FIG. 14 is a diagram for describing a substrate treatment method using the above-described substrate treatment device according to the fourth embodiment of the present invention.

FIG. 15 is a diagram for describing a substrate treatment method using the above-described substrate treatment device illustrated in FIG. 2B.

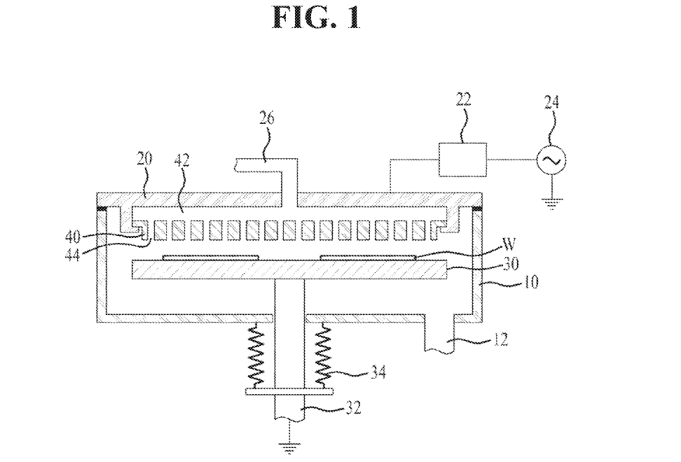

### MODE FOR INVENTION

Hereinafter, embodiments will be described in detail with reference to the accompanying drawings. Since the inventive concept may have diverse modified embodiments, preferred embodiments are illustrated in the drawings and are described in the detailed description of the invention. However, this does not limit the inventive concept within specific embodiments and it should be understood that the inventive concept covers all the modifications, equivalents, and replacements within the idea and technical scope of the inventive concept. In the drawings, the size or shape of each element may be exaggerated for clarity and convenience of description.

Terms like a first and a second may be used to describe various elements, but the elements should not be limited by the terms. The terms may be used only as object for distinguishing an element from another element. Also, terms which are specially defined in consideration of a function and an operation of an embodiment are for merely describing an embodiment, and do not limit the scope of an embodiment.

In describing embodiments, in a case of being described as being formed above (on) or below (under) each element includes, “above (on)” or “below (under)” includes two elements directly contacting each other or one or more elements being indirectly disposed between the two elements. Also, a case of being expressed as above (on) or below (under) may include a down direction as well as an up direction with respect to one element.

Moreover, relational terms such as “above/upper/on” and “below/lower/under” used below may be used only for differentiating any one substance or element from another substance or element without necessarily desiring or including any physical or logical relationship or order between such substances or elements.

Hereinafter, preferable embodiments according to the present invention will be described in detail with reference to the drawings.

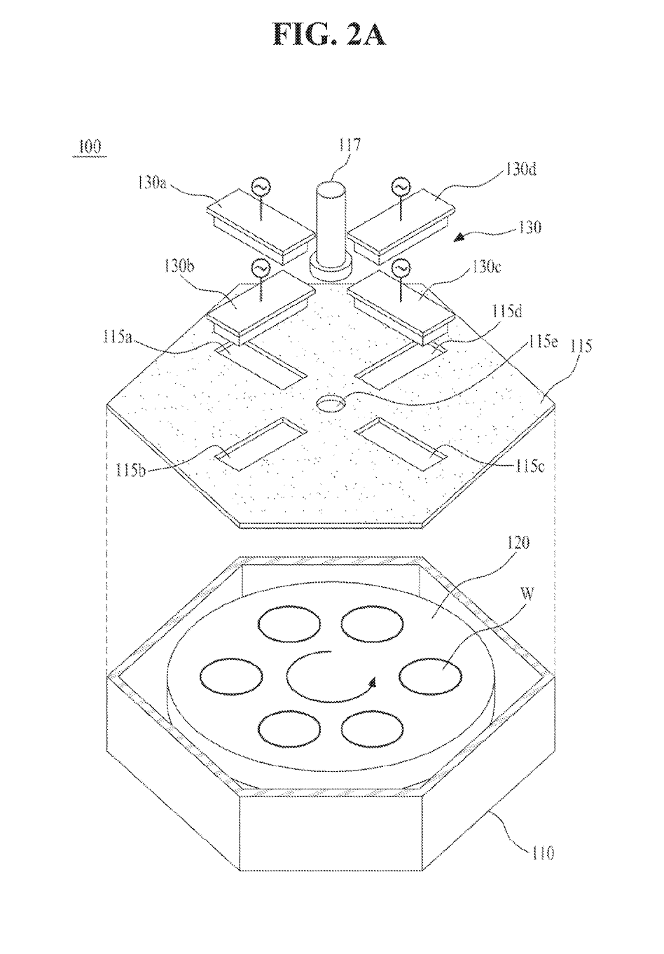

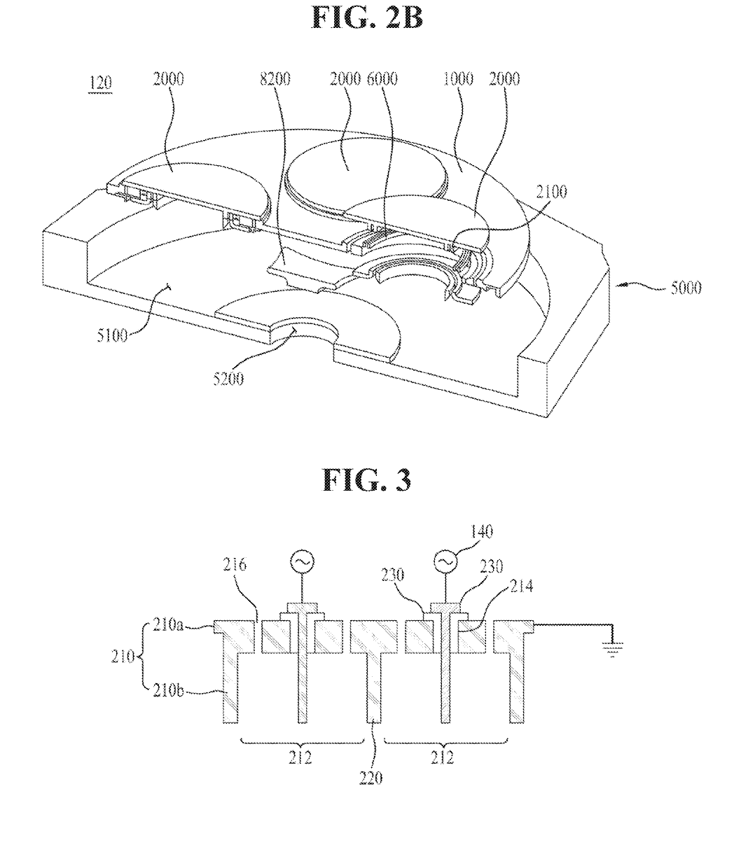

FIG. 2A is a diagram for schematically describing a substrate treatment device according to a first embodiment of the present invention, and FIG. 3 is a cross-sectional view schematically illustrating a cross-sectional surface of a gas distribution module illustrated in FIG. 2A.

Referring to FIGS. 2A and 3, a substrate treatment device 100 according to the first embodiment of the present invention includes a process chamber 110, a chamber lid 115, a substrate supporting part 120, and a gas distribution unit 130.

The process chamber 110 provides a reaction space for a substrate processing process, for example, a thin film deposition process. A floor surface or a side surface of the process chamber 110 communicates with an exhaust pipe (not shown) for exhausting a gas or the like in the reaction space.

The chamber lid 115 is installed on the process chamber 110 to cover a top of the process chamber 110. The chamber lid 115 supports the gas distribution unit 130 and includes a plurality of module installation part 115a to 115d which the gas distribution unit 130 is inserted into and is installed in. In this case, the plurality of module installation part 115a to 115d may be provided in the chamber lid 115 and may be spaced apart from each other in units of 90 degrees to be symmetric about a center point of the chamber lid 115 in a diagonal direction.

In FIG. 2A, the chamber lid 115 is illustrated as including four module installation parts 115a to 115d, but is not limited thereto. The chamber lid 115 may include 2N (where N is a natural number) number of module installation parts which are symmetric about the center point. In this case, the plurality of module installation parts are symmetric about the center point of the chamber lid 115 in the diagonal direction. Hereinafter, the chamber lid 115 will be described on the assumption of including first to fourth module installation parts 115a to 115b.

The above-described reaction space of the process chamber 110 sealed by the chamber lid 115 is coupled to an external pumping means (not shown) through a pumping pipe 117 installed in the chamber lid 115.

The pumping pipe 117 communicates with the reaction space of the process chamber 110 through a pumping hole 115e provided in a center portion of the chamber lid 115. Therefore, the inside of the process chamber 110 is put in a vacuum state or an atmospheric pressure state according to a pumping operation of the pumping means which is performed through the pumping pipe 117.

The substrate supporting part 120 is rotatably installed in the process chamber 110. The substrate supporting part 120 is supported by a rotation shaft (not shown) passing through a central floor surface of the process chamber 110. The rotation shaft rotates according to driving of a shaft driving member (not shown) to rotate the substrate supporting part 120 in a certain direction. Also, the rotation shaft exposed to the outside is sealed by bellows (not shown) installed on a bottom of the process chamber 110.

The substrate supporting parts 120 support a plurality of substrates W loaded from an external substrate loading apparatus (not shown). In this case, the substrate supporting part 120 has a circular plate shape, and the plurality of substrates W (for example, semiconductor substrates or wafers) are arranged in a circular type at certain intervals.

FIG. 2B is a cross-sectional perspective view illustrating in more detail the substrate supporting part 120 in the substrate treatment device according to an embodiment of the present invention. The substrate treatment device according to an embodiment may include a first disk 1000, a second disk 2000, a metal ring 3000, a bearing 6000, and a frame 5000.

The first disk 1000 may be accommodated into an accommodating part 5100 included in the frame 5000 and may be provided to perform a first rotation (i.e., to be rotatable) with respect to the frame 5000. The below-described second disk 2000 may be provided in the first disk 1000 and may be symmetric about a center of the first disk 1000.

The first disk 1000, as illustrated in FIG. 2B, may be mounted on the frame 5000. In this case, the accommodating part 5100 where the first disk 1000 is disposed may be grooved and provided in the frame 5000 to have an area and a shape corresponding to an area and a shape of the first disk 1000.

If the second disk 2000 is included in the first disk 1000, a various number of second disks 2000 may be radially disposed on the first disk 1000 depending on a size thereof. Also, a disk receiving part where the second disk 2000 is disposed may be grooved and provided on the first disk 1000 to have an area and a shape corresponding to an area and a shape of the second disk 2000.

The second disk 2000 may be disposed on the first disk 1000, and a substrate may be disposed on a top of the second disk 2000. As the first disk 1000 rotates, the second disk 2000 may rotate and may perform a second rotation (i.e., revolution) with respect to a center of the first disk 1000.

A substrate (not shown) may be disposed on the top of the second disk 2000. In this case, if the second disk 2000 is circular as in an embodiment, the substrate may be, for example, a circular wafer. Therefore, substrate processing may be performed by distributing a process gas, including a source material and/or the like, to a substrate such as a wafer disposed on the top of the second disk 2000.

Moreover, the second disk 2000 revolves about a center of a first substrate and simultaneously rotates about a center of the second disk 2000, and thus, a deposition layer or an etching shape may be formed on a circular substrate disposed on the second disk 2000 and may be symmetric about a center of the substrate.

Moreover, the second disk 2000 revolves about the center of the first disk 1000 and simultaneously rotates about the center of the second disk 2000, and a rotation speed of the first disk 1000 may differ from that of the second disk 2000. If the rotation speed of the first disk 1000 differs from that of the second disk 2000, constant deposition uniformity on a substrate (not shown) is maintained in a deposition process performed on the substrate (not shown) on the second disk 2000.

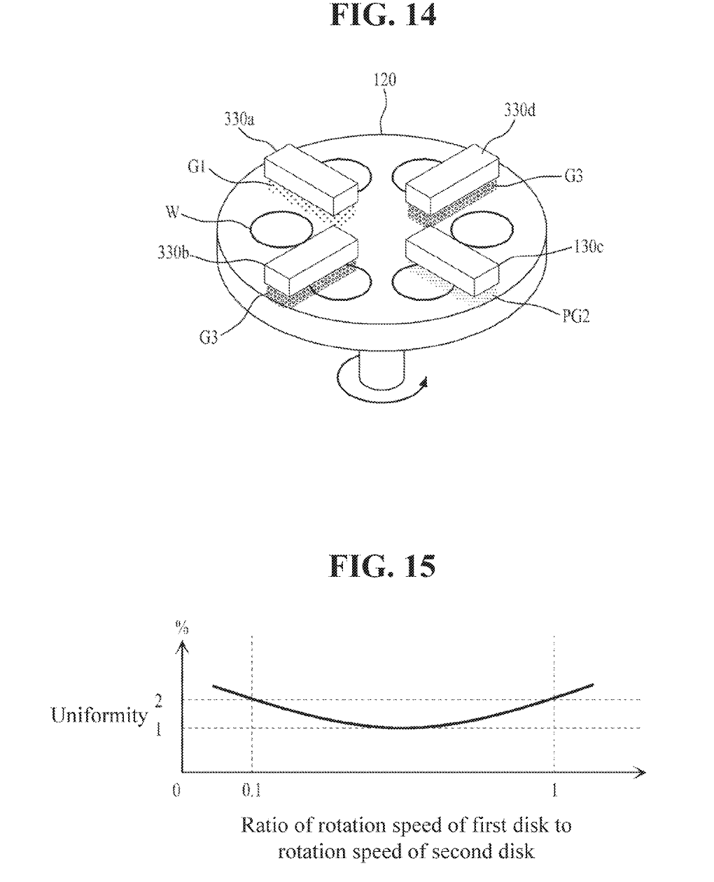

In a ratio of the rotation speed of the first disk 1000 to a rotation speed of the second disk 2000, as seen in FIG. 15, when the rotation speed of the first disk 1000 is set to 1, deposition uniformity on a substrate can be maintained as 1% to 2% in a case where a ratio of the rotation speed of the second disk 2000 corresponds to a speed of 0.1 or more and less than 1.

In a case where a ratio of the rotation speed of the first disk 1000 to the rotation speed of the second disk 2000 is 1:less than 0.1 and 1:1 or more, a flow of a distributed process gas in a process space is affected by a rotation speed, and for this reason, deposition uniformity on a substrate cannot be constant.

A first supporting part 2100 may be provided under the second disk 2000. The first supporting part 2100 may be provided under the second disk 2000 to protrude.

The gas distribution unit 130 is inserted into and installed in each of the first to fourth module installation parts 115a to 115d provided in the chamber lid 115. The gas distribution unit 130 spatially separates and distributes a first gas and a second gas to a plurality of substrates W that rotate according to a rotation of the substrate supporting part 120.

The first gas may be a source gas including a thin film material which is to be deposited on the substrate W. The source gas may contain silicon (Si), titan group element (Ti, Zr, Hf, etc.), aluminum (Al), etc. For example, the source gas containing Si may be silane (SiH₄), disilane (Si₂H₆), trisilane (Si₃H₈), tetraethylorthosilicate (TEOS), dichlorosilane (DCS), hexachlorosilane (HCD), tri-dimethylaminosilane (TriDMAS), trisilylamine (TSA), and/or the like.

The second gas may consist of a reactant gas that reacts with the source gas to allow a thin film material contained in the source gas to be deposited on the substrate W. For example, the reactant gas may consist of at least one kind of gas among nitrogen (N₂), oxygen (O₂), nitrogen dioxide (N₂O), and ozone (O₃).

The gas distribution unit 130 includes first to fourth gas distribution modules 130a to 130d that are respectively inserted into and installed in the first to fourth module installation parts 115a to 115d provided in the chamber lid 115 and spatially separate and distribute the first and second gases to first to fourth gas distribution areas which are spatially separated from each other and are defined on the substrate supporting part 120.

The first to fourth gas distribution modules 130a to 130d are respectively inserted into and installed in the first to fourth module installation parts 115a to 115d of the chamber lid 115 and are disposed to be symmetric with each other in an X-axis direction and a Y-axis direction about a center point of the substrate supporting part 120.

The first gas distribution module 130a is inserted into and installed in the first module installation part 115a overlapping the first gas distribution area defined on the substrate supporting part 120 and downward distributes the first gas, which has become plasmatic, to the first gas distribution area. To this end, the first gas distribution module 130a includes a ground frame 210, a ground partition wall member 220, a plurality of insulation members 230, and a plurality of plasma electrode members 240.

The ground frame 210 is provided to have a bottom which is open, in order to have a plurality of gas distribution spaces 212 separated from each other by the ground partition wall member 220. The ground frame 210 is inserted into and installed in the first module installation part 115a of the chamber lid 115 and is electrically grounded through the chamber lid 115. To this end, the ground frame 210 includes a top plate 210a and ground side walls 210b.

The top plate 210a is provided in a rectangular shape and is coupled to the first module installation part 115a of the chamber lid 115. A plurality of insulation member supporting holes 214 and a plurality of gas supply holes 216 are provided in the top plate 210a.

The plurality of insulation member supporting holes 214 pass through the top plate 210a and respectively communicate with the plurality of gas distribution spaces 212. Each of the plurality of insulation member supporting holes 214 is provided to have a rectangular plane.

The plurality of gas supply holes 216 pass through the top plate 210a and respectively communicate with the plurality of gas distribution spaces 212. Each of the plurality of gas supply holes 216 is coupled to an external gas supply means (not shown) through the gas supply pipe and is supplied with the first gas through the gas supply pipe from the gas supply means (not shown).

Each of the ground side walls 210b vertically protrudes from a long side edge and a short side edge of the top plate 210a to provide the gas distribution space 212 under the top plate 210a. Each of the ground side walls 210b is electrically grounded through the chamber lid 115. In this case, each of the long side ground side walls act as a ground electrode.

The ground partition wall member 220 vertically protrudes from a center bottom of the top plate 210a and is disposed in parallel with long sides of the ground side walls 210b. The ground partition wall member 220 is provided in the ground frame 210 to have a certain height, thereby providing the plurality of gas distribution spaces 212, which are spatially separated from each other, in the ground frame 210. The ground partition wall member 220 is integrated with or electrically coupled to the ground frame 210 and is electrically grounded through the ground frame 210, thereby acting as a ground electrode.

The long sides of the ground side walls 210b and the ground partition wall member 220 are arranged in parallel at certain intervals in the ground frame 210 to configure a plurality of ground electrode members.

Each of the plurality of insulation members 230 is formed of an insulating material, inserted into the insulation member supporting hole 214 provided in the ground frame 210, and coupled to a top of the ground frame 210 by a fastening member (not shown).

Each of the plurality of plasma electrode members 240 is formed of a conductive material and is inserted into the insulation member 230 to pass through the insulation member 230, and protrudes by a certain height from a bottom of the ground frame 210, whereby each of the plasma electrode members 240 is disposed in the gas distribution space 212. In this case, each of the plurality of plasma electrode members 240 protrudes by the same height as the ground partition wall member 220 and the side walls 210b of the ground frame 210. Therefore, the plurality of plasma electrode members 240 are alternately arranged at certain intervals in parallel with the above-described ground electrode member.

The plasma electrode member 240 is electrically connected to a plasma power supply unit 140 through a feeder cable and generates plasma in the gas distribution space 212 according to a plasma power supplied from the plasma power supply unit 140. Therefore, the plasma makes the first gas supplied to the gas distribution space 212 plasmatic, and the plasmatic first gas is downward distributed to the first gas distribution area. The plasmatic first gas may be downward distributed from the gas distribution space 212 by a flow velocity (or a flow) of the first gas supplied to the gas distribution space 212.

The plasma power supply unit 140 generates the plasma power having a certain frequency and supplies the plasma power to each of the first to fourth gas distribution modules 130a to 130d through the feeder cable in common or individually. In this case, a high frequency (HF) power or a very high frequency (VHF) power is supplied as the plasma power. For example, the HF power may have a frequency of 3 MHz to 30 MHz, and the VHF power may have a frequency of 30 MHz to 300 MHz.

An impedance matching circuit (not shown) is connected to the feeder cable.

The impedance matching circuit matches a source impedance and a load impedance of the plasma power which is supplied from the plasma power supply unit 140 to each of the first to fourth gas distribution modules 130a to 130d. The impedance matching circuit may be configured with at least two impedance elements (not shown) which include at least one of a variable capacitor and a variable inductor.

The first gas distribution module 130a generates the plasma in the gas distribution space 212 according to the plasma power supplied from the plasma power supply unit 140 to the plasma electrode member 240, makes the first gas supplied to the gas distribution space 212 plasmatic, and downward distributes the plasmatic first gas to the first gas distribution area.

The second gas distribution module 130b is inserted into and installed in the second module installation part 115b overlapping the second gas distribution area which is defined on the substrate supporting part 120 to be spatially separated from the above-described first gas distribution area, and downward distributes the second gas, which has become plasmatic, to the second gas distribution area. To this end, as illustrated in FIG. 3, the second gas distribution module 130b includes a ground frame 210, a ground partition wall member 220, a plurality of insulation members 230, and a plurality of plasma electrode members 240, and the above-described descriptions are applied to the elements. By using such elements, the second gas distribution module 130b is electrically connected to the plasma power supply unit 140 through a feeder cable to generate plasma in the gas distribution space 212 according to the plasma power supplied from the plasma power supply unit 140, makes the second gas supplied to the gas distribution space 212 plasmatic, and downward distributes the plasmatic second gas to the second gas distribution area.

The third gas distribution module 130c is inserted into and installed in the third module installation part 115c overlapping the third gas distribution area which is defined on the substrate supporting part 120 to be spatially separated from the above-described second gas distribution area, and downward distributes the first gas, which has become plasmatic, to the third gas distribution area. To this end, as illustrated in FIG. 3, the third gas distribution module 130c includes a ground frame 210, a ground partition wall member 220, a plurality of insulation members 230, and a plurality of plasma electrode members 240, and the above-described descriptions are applied to the elements. By using such elements, the third gas distribution module 130c is electrically connected to the plasma power supply unit 140 through a feeder cable to generate plasma in the gas distribution space 212 according to the plasma power supplied from the plasma power supply unit 140, makes the first gas supplied to the gas distribution space 212 plasmatic, and downward distributes the plasmatic first gas to the third gas distribution area.

The fourth gas distribution module 130d is inserted into and installed in the fourth module installation part 115d overlapping the fourth gas distribution area which is defined on the substrate supporting part 120 between the first and third gas distribution areas to be spatially separated from the above-described first and third gas distribution areas, and downward distributes the second gas, which has become plasmatic, to the fourth gas distribution area. To this end, as illustrated in FIG. 3, the fourth gas distribution module 130d includes a ground frame 210, a ground partition wall member 220, a plurality of insulation members 230, and a plurality of plasma electrode members 240, and the above-described descriptions are applied to the elements. By using such elements, the fourth gas distribution module 130d is electrically connected to the plasma power supply unit 140 through a feeder cable to generate plasma in the gas distribution space 212 according to the plasma power supplied from the plasma power supply unit 140, makes the second gas supplied to the gas distribution space 212 plasmatic, and downward distributes the plasmatic second gas to the fourth gas distribution area.

In the substrate treatment device 100 according to the first embodiment of the present invention, the first to fourth gas distribution modules 130a to 130d are spatially separated from each other and are disposed on the substrate supporting part 120, and the first and second gases which have become plasmatic by using each of the first to fourth gas distribution modules 130a to 130d are spatially separated from each other and are distributed to the substrate supporting part 120, thereby increasing the deposition uniformity of the thin film deposited on each substrate W through reaction between the plasmatic first and second gases, facilitating the control of quality of the thin film, and minimizing an accumulation thickness deposited in the process chamber 110 to reduce particles.

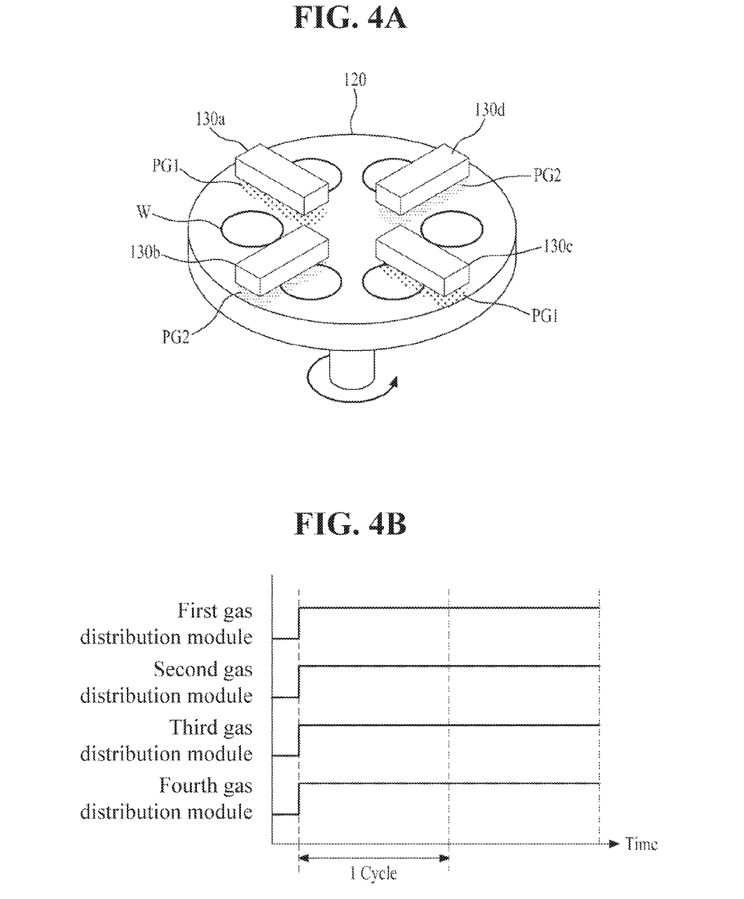

FIG. 4A is a diagram for describing a substrate treatment method using the above-described substrate treatment device according to the first embodiment of the present invention, and FIG. 4B is a waveform diagram for describing an operation sequence of the first to fourth gas distribution modules illustrated in FIG. 4A. The substrate treatment method using the substrate treatment device according to the first embodiment of the present invention will be briefly described with reference to FIGS. 3, 4A and 4B.

First, the plurality of substrates W are loaded onto the substrate supporting part 120 at certain intervals.

Subsequently, the substrate supporting part 120 onto which the plurality of substrates W are loaded rotates in a certain direction.

Subsequently, the first gas is supplied to the gas distribution space 212 of each of the first and third gas distribution modules 130a and 130c, and the plasma power is applied to the plasma electrode member 240 of each of the first and third gas distribution modules 130a and 130c, thereby downward distributing a plasmatic first gas PG1 to each of the first and third gas distribution areas on the substrate supporting part 120. At this time, the plasmatic first gas PG1 is continuously distributed irrespective of a process cycle where the substrate supporting part 120 rotates in a certain direction once.

Simultaneously, the second gas is supplied to the gas distribution space 212 of each of the second and fourth gas distribution modules 130b and 130d, and the plasma power is applied to the plasma electrode member 240 of each of the second and fourth gas distribution modules 130b and 130d, thereby downward distributing a plasmatic second gas PG2 to each of the second and fourth gas distribution areas on the substrate supporting part 120. At this time, the plasmatic second gas PG2 is continuously distributed irrespective of the process cycle.

Therefore, each of the plurality of substrates W disposed on the substrate supporting part 120 passes through the first to fourth gas distribution areas according to a rotation of the substrate supporting part 120, and thus, a thin film material is deposited on each of the plurality of substrates W by reaction between the plasmatic first and second gases PG1 and PG2 which are spatially separated from each other and are distributed from each of the first to fourth gas distribution modules 130a to 130d.

In the above-described substrate treatment device and substrate treatment method, it has been described that each of the first to fourth gas distribution modules 130a to 130d simultaneously distributes the plasmatic first and second gases PG1 and PG2, but the plasmatic first and second gases PG1 and PG2 may be distributed according to an operation sequence based on control by a control module (not shown) without being limited thereto.

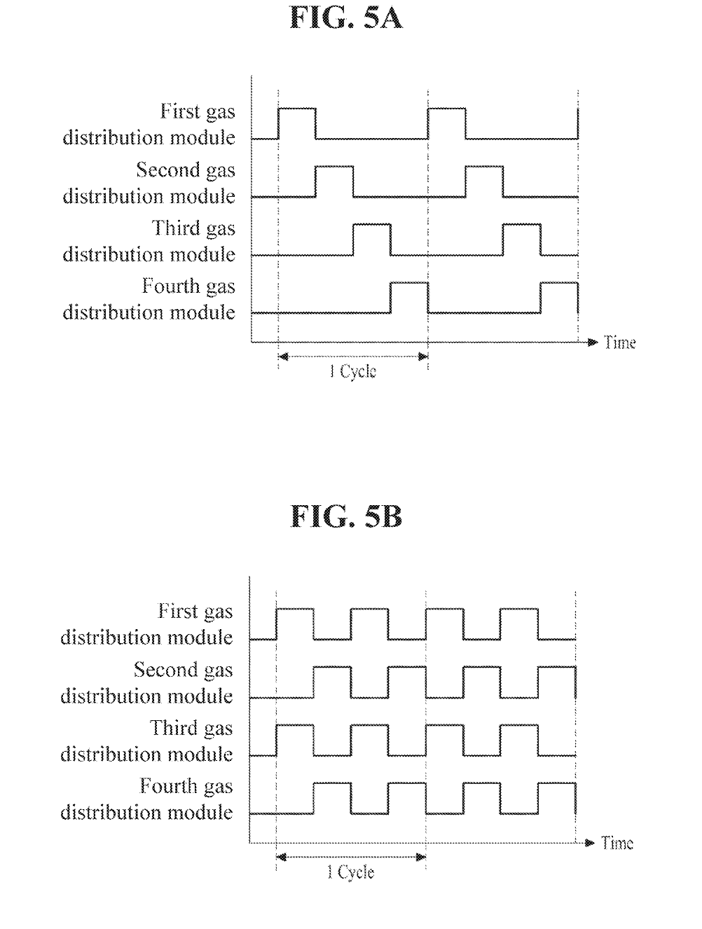

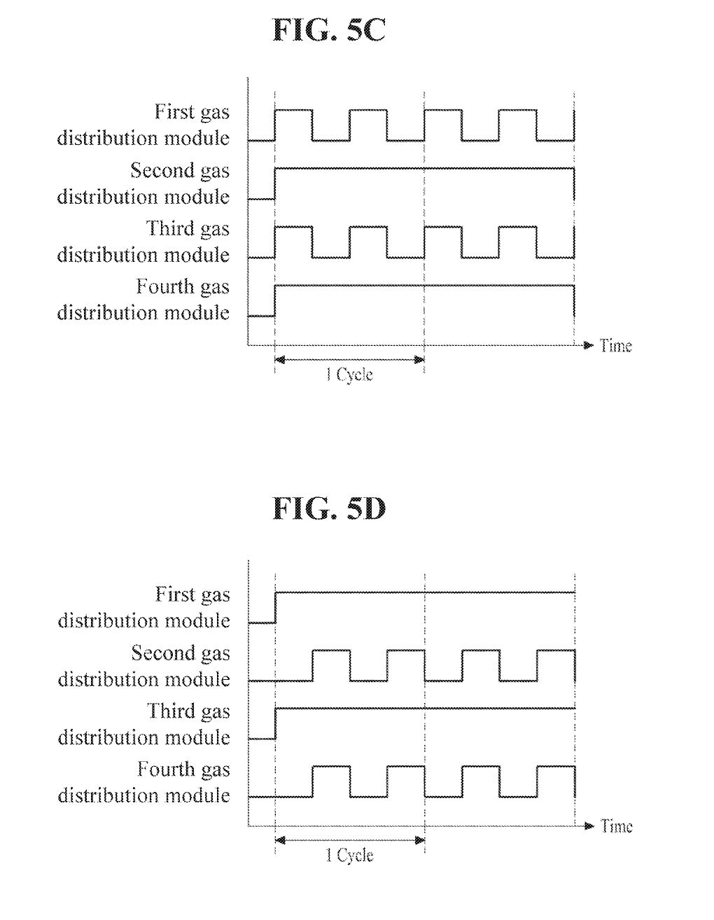

FIGS. 5A to 5D are waveform diagrams for describing modification examples of a substrate treatment method using the first to fourth gas distribution modules illustrated in FIG. 2.

As seen in FIG. 5A, a substrate treatment method according to a first modification embodiment sequentially performs an operation of each of the first to fourth gas distribution modules 130a to 130d to sequentially distribute the plasmatic first and second gases PG1 and PG2 at every process cycle. In this case, each process cycle may include first to fourth sections. The substrate treatment method according to the first modification embodiment will be described in detail below.

First, the plasmatic first gas PG1 is distributed to the first gas distribution area through only the first gas distribution module 130a in the first section of each process cycle.

Subsequently, in the second section of each process cycle, gas distribution performed through the first gas distribution module 130a is stopped, and the plasmatic second gas PG2 is distributed to the second gas distribution area through only the second gas distribution module 130b.

Subsequently, in the third section of each process cycle, gas distribution performed through the second gas distribution module 130b is stopped, and the plasmatic first gas PG1 is distributed to the third gas distribution area through only the third gas distribution module 130c.

Subsequently, in the fourth section of each process cycle, gas distribution performed through the third gas distribution module 130c is stopped, and the plasmatic second gas PG2 is distributed to the fourth gas distribution area through only the fourth gas distribution module 130d.

As seen in FIG. 5B, a substrate treatment method according to a second modification embodiment may alternately perform operations of the first and third gas distribution modules 130a and 130c and operations of the second and fourth gas distribution modules 130b and 130d to alternately distribute the plasmatic first and second gases PG1 and PG2 at every process cycle. In this case, each process cycle may include first to fourth sections. The substrate treatment method according to the second modification embodiment will be described in detail below.

First, the plasmatic first gas PG1 is simultaneously distributed to the first and third gas distribution areas through only the first and third gas distribution modules 130a and 130c in the first section of each process cycle.

Subsequently, in the second section of each process cycle, gas distribution performed through the first and third gas distribution modules 130a and 130c is stopped, and the plasmatic second gas PG2 is simultaneously distributed to the second and fourth gas distribution areas through only the second and fourth gas distribution modules 130b and 130d.

Subsequently, in the third section of each process cycle, gas distribution performed through the second and fourth gas distribution modules 130b and 130d is stopped, and the plasmatic first gas PG1 is simultaneously distributed to the first and third gas distribution areas through only the first and third gas distribution modules 130a and 130c.

Subsequently, in the fourth section of each process cycle, gas distribution performed through the first and third gas distribution modules 130a and 130c is stopped, and the plasmatic second gas PG2 is simultaneously distributed to the second and fourth gas distribution areas through only the second and fourth gas distribution modules 130b and 130d.

As seen in FIG. 5C, a substrate treatment method according to a third modification embodiment may simultaneously distribute the plasmatic first gas PG1 to the first and third gas distribution areas through the first and third gas distribution modules 130a and 130c at every certain section of each process cycle and may continuously and simultaneously distribute the plasmatic second gas PG2 to the second and fourth gas distribution areas through the second and fourth gas distribution modules 130b and 130d.

As seen in FIG. 5D, a substrate treatment method according to a fourth modification embodiment may continuously and simultaneously distribute the plasmatic first gas PG1 to the first and third gas distribution areas through the first and third gas distribution modules 130a and 130c and at every certain section of each process cycle, may simultaneously distribute the plasmatic second gas PG2 to the second and fourth gas distribution areas through the second and fourth gas distribution modules 130b and 130d.

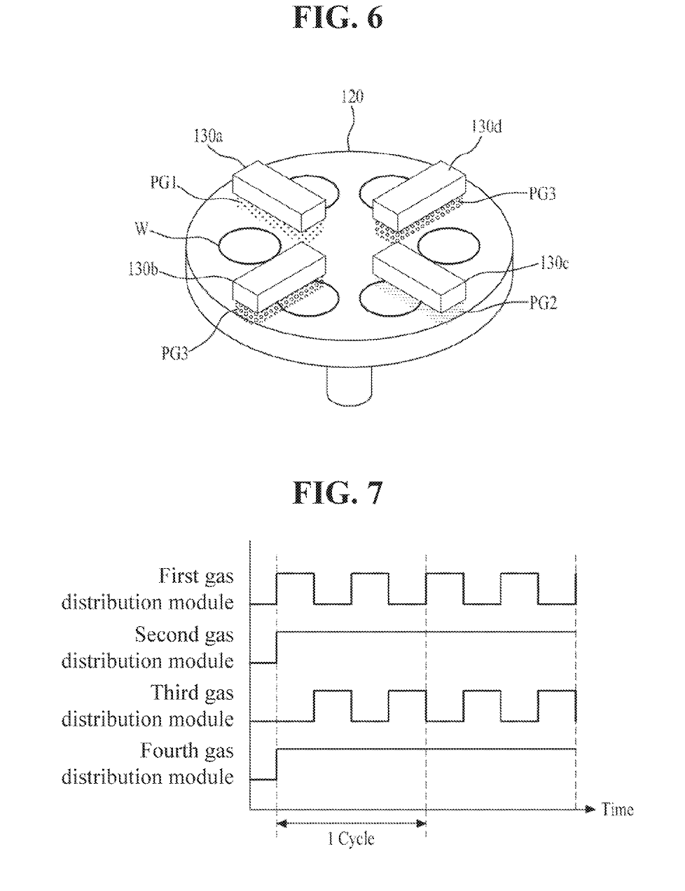

FIG. 6 is a diagram for describing a modification embodiment of the substrate treatment device according to the first embodiment of the present invention.

Referring to FIG. 6, except for the kind of a gas distributed from each of the first to fourth gas distribution modules 130a to 130d, a substrate treatment device according to a modification embodiment of the first embodiment of the present invention is the same as the substrate treatment device illustrated in FIG. 2A. Hereinafter, therefore, only the kind of a gas distributed from each of the first to fourth gas distribution modules 130a to 130d will be described.

The first gas distribution module 130a is supplied with the above-described first gas from the gas supply means and downward distributes the plasmatic first gas to the first gas distribution area.

The second gas distribution module 130b is supplied with a third gas from the gas supply means and downward distributes a plasmatic third gas PG3 to the second gas distribution area. In this case, the third gas may be a purge gas for purging the above-described first and second gases. The third gas is for purging a first gas, which remains without being deposited on the substrate W, and/or a second gas which remains without reacting with the first gas, and may consist of at least one kind of gas of nitrogen (N₂), argon (Ar), xenon (Ze), and helium (He).

The third gas distribution module 130c is supplied with the above-described second gas from the gas supply means and downward distributes the plasmatic second gas to the third gas distribution area.

The fourth gas distribution module 130d is supplied with the third gas from the gas supply means and downward distributes the plasmatic third gas PG3 to the fourth gas distribution area.

FIG. 7 is a waveform diagram for describing an operation sequence of the first to fourth gas distribution modules illustrated in FIG. 6.

A substrate treatment method using the substrate treatment device according to the modification embodiment of the first embodiment of the present invention will be briefly described with reference to FIGS. 6 and 7.

First, the plurality of substrates W are loaded onto the substrate supporting part 120 at certain intervals.

Subsequently, the substrate supporting part 120 onto which the plurality of substrates W are loaded rotates in a certain direction.

Subsequently, first and second gases G1 and G2 are spatially separated from each other and are alternately distributed through the first and third gas distribution modules 130a and 130c at every certain section, and the plasmatic third gas PG3 is continuously distributed through the second and fourth gas distribution modules 130b and 130d.

Therefore, a thin film material is deposited on each of the plurality of substrates W, disposed on the substrate supporting part 120 which is rotating, by reaction between the plasmatic first and second gases PG1 and PG2 which are spatially separated from each other and are distributed from each of the first to fourth gas distribution modules 130a to 130d. At this time, the plasmatic third gas PG3 prevents the plasmatic first and second gases PG1 and PG2 from being mixed and reacting with each other in the middle of being distributed to the substrate W and allows the plasmatic first and second gases PG1 and PG2 to be distributed to a top of the substrate W, mixed, and react.

As described above, in the substrate treatment device and the substrate treatment method according to the modification embodiment of the first embodiment of the present invention, a third gas G3 prevents mixing of the plasmatic first and second gases PG1 and PG2 distributed to each substrate W, thereby further increasing the quality and deposition uniformity of a thin film deposited on each substrate W.

Moreover, the substrate treatment method using the substrate treatment device according to the modification embodiment of the first embodiment of the present invention may operate each of the first to fourth gas distribution modules 130a to 130d according to an operation sequence illustrated in FIGS. 4B and 5A to 5D, and thus, the above-described plasmatic first to third gases PG1 to PG3 may be spatially separated from each other and may be distributed to the first to fourth gas distribution areas.

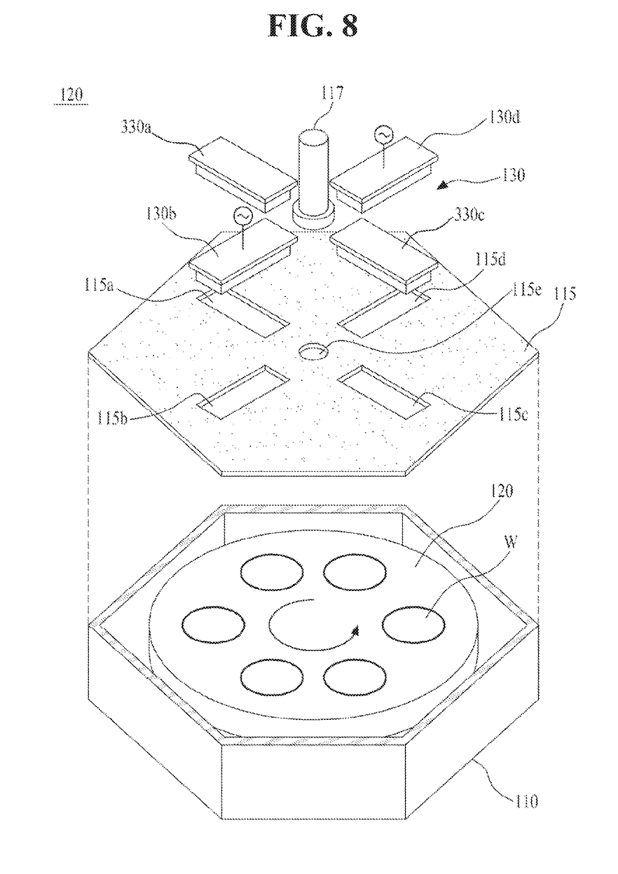

FIG. 8 is a diagram schematically illustrating a substrate treatment device according to a second embodiment of the present invention.

Referring to FIG. 8, a substrate treatment device 200 according to the second embodiment of the present invention includes a process chamber 110, a chamber lid 115, a substrate supporting part 120, and a gas distribution unit 130. Except for the gas distribution unit 130, the elements of the substrate treatment device 200 are the same as those of the above-described substrate treatment device 100, and thus, the above descriptions are applied to the same elements.

The gas distribution unit 130 is inserted into and installed in each of first to fourth module installation parts 115a to 115d provided in the chamber lid 115. The gas distribution unit 130 spatially separates a first gas which does not become plasmatic and a second gas which becomes plasmatic, and downward distributes the spatially separated first and second gases toward the substrate supporting part 120. To this end, the gas distribution unit 130 includes a first gas distribution module 330a, a second gas distribution module 130b, a third gas distribution module 330c, and a fourth gas distribution module 130d.

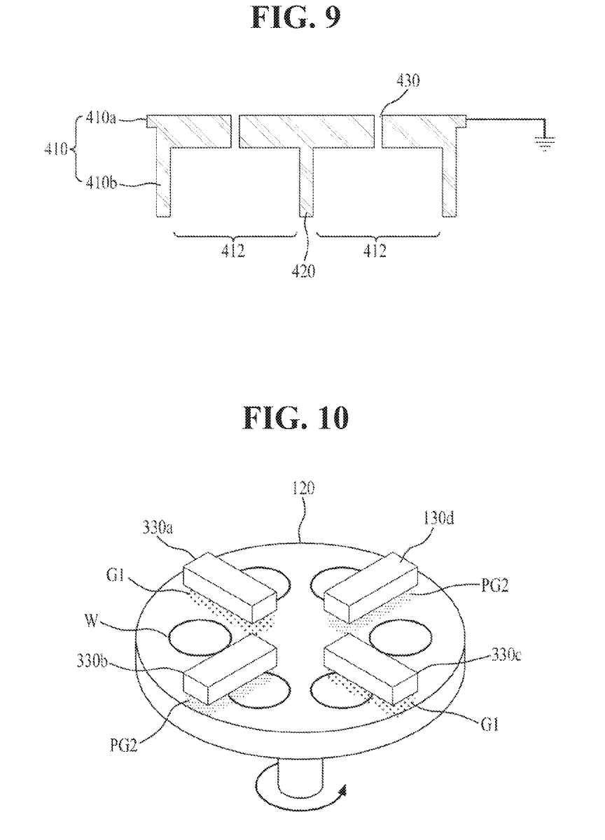

The first gas distribution module 330a is inserted into and installed in the second module installation part 115b overlapping the above-described first gas distribution area and downward distributes the first gas, supplied from the gas supply means, to the first gas distribution area as-is. To this end, as illustrated in FIG. 9, the first gas distribution module 330a includes a ground frame 410, a ground partition wall member 420, and a plurality of gas supply holes 430.

The ground frame 410 is provided to have a bottom which is open, in order to have a plurality of gas distribution spaces 412 separated from each other by the ground partition wall member 420. The ground frame 410 is inserted into and installed in the first module installation part 115a of the chamber lid 115 and is electrically grounded through the chamber lid 115. To this end, the ground frame 410 includes a top plate 410a and ground side walls 410b.

The top plate 410a is provided in a rectangular shape and is coupled to the first module installation part 115a of the chamber lid 115.

Each of the ground side walls 410b vertically protrudes from a long side edge and a short side edge of the top plate 410a to provide the gas distribution space 412 under the top plate 410a. Each of the ground side walls 410b is electrically grounded through the chamber lid 115. In this case, each of the long side ground side walls act as a ground electrode.

The ground partition wall member 420 vertically protrudes from a center bottom of the top plate 410a and is disposed in parallel with long sides of the ground side walls 410b. The ground partition wall member 420 is provided in the ground frame 410 to have a certain height, thereby providing the plurality of gas distribution spaces 412, which are spatially separated from each other, in the ground frame 410. The ground partition wall member 420 is integrated with or electrically coupled to the ground frame 410 and is electrically grounded through the ground frame 410, thereby acting as a ground electrode.

The long sides of the ground side walls 410b and the ground partition wall member 420 are arranged in parallel at certain intervals in the ground frame 410 to configure a plurality of ground electrode members.

The plurality of gas supply holes 430 pass through the top plate 410a of the ground frame 410 and respectively communicate with the plurality of gas distribution spaces 412. Each of the plurality of gas supply holes 430 is coupled to the external gas supply means through the gas supply pipe and is supplied with the first gas through the gas supply pipe from the gas supply means.

The first gas distribution module 330a downward distributes the first gas, supplied from the gas supply means to the gas distribution space 412, to the first gas distribution area as-is without being plasmatic. That is, since a plasma electrode member is not installed in the first gas distribution module 330a unlike the first gas distribution module 130a illustrated in FIG. 2A, the first gas distribution module 330a downward distributes the first gas supplied to the gas distribution space 412 as-is. Therefore, the first gas supplied to the first gas distribution module 330a includes a thin film material which is capable of being deposited on a substrate by reacting with the second gas even without being plasmatic by plasma.

The second gas distribution module 130b is inserted into and installed in the second module installation part 115b overlapping the above-described first gas distribution area, and downward distributes the second gas, which has become plasmatic, to the second gas distribution area. To this end, as illustrated in FIG. 3, the second gas distribution module 130b includes a ground frame 210, a ground partition wall member 220, a plurality of insulation members 230, and a plurality of plasma electrode members 240, and the above-described descriptions are applied to the elements. By using such elements, the second gas distribution module 130b is electrically connected to the plasma power supply unit 140 through a feeder cable to generate plasma in the gas distribution space 212 according to the plasma power supplied from the plasma power supply unit 140, makes the second gas supplied to the gas distribution space 212 plasmatic, and downward distributes the plasmatic second gas to the second gas distribution area.

The third gas distribution module 330c is inserted into and installed in the third module installation part 115c overlapping the above-described third gas distribution area, and downward distributes the first gas, supplied from the gas supply means, to the third gas distribution area as-is without being plasmatic. To this end, the third gas distribution module 330c has the same configuration as that of the first gas distribution module 330a illustrated in FIG. 9, and thus, the description on the first gas distribution module 330a is applied to the third gas distribution module 330c.

The fourth gas distribution module 130d is inserted into and installed in the fourth module installation part 115d overlapping the above-described fourth gas distribution area, and downward distributes the second gas, which has become plasmatic, to the fourth gas distribution area. To this end, as illustrated in FIG. 3, the fourth gas distribution module 130d includes a ground frame 210, a ground partition wall member 220, a plurality of insulation members 230, and a plurality of plasma electrode members 240, and the above-described descriptions are applied to the elements. By using such elements, the fourth gas distribution module 130d is electrically connected to the plasma power supply unit 140 through a feeder cable to generate plasma in the gas distribution space 212 according to the plasma power supplied from the plasma power supply unit 140, makes the second gas supplied to the gas distribution space 212 plasmatic, and downward distributes the plasmatic second gas to the second gas distribution area.

FIG. 10 is a diagram for describing a substrate treatment method using the above-described substrate treatment device according to the second embodiment of the present invention.

A substrate treatment method using the substrate treatment device according to the second embodiment of the present invention will be described with reference to FIG. 10.

First, a plurality of substrates W are loaded onto the substrate supporting part 120 at certain intervals.

Subsequently, the substrate supporting part 120 onto which the plurality of substrates W are loaded rotates in a certain direction.

Subsequently, the first gas is supplied to the gas distribution space 412 of each of the first and third gas distribution modules 330a and 330c, thereby downward distributing a first gas G1 to each of the first and third gas distribution areas. At this time, the first gas G1 is continuously distributed irrespective of a process cycle where the substrate supporting part 120 rotates in a certain direction once.

Simultaneously, the second gas is supplied to the gas distribution space 212 of each of the second and fourth gas distribution modules 130b and 130d, and the plasma power is applied to the plasma electrode member 240 of each of the second and fourth gas distribution modules 130b and 130d, thereby downward distributing a plasmatic second gas PG2 to each of the second and fourth gas distribution areas on the substrate supporting part 120. At this time, the plasmatic second gas PG2 is continuously distributed irrespective of the process cycle.

Therefore, each of the plurality of substrates W disposed on the substrate supporting part 120 passes through the first to fourth gas distribution areas according to a rotation of the substrate supporting part 120, and thus, a thin film material is deposited on each of the plurality of substrates W by reaction between the first gas G1 and the plasmatic second gas PG2 which are spatially separated from each other and are distributed from each of the first gas distribution module 330a, the second gas distribution module 130b, the third gas distribution module 330c, and the fourth gas distribution module 130d.

In the above-described substrate treatment device and substrate treatment method of the second embodiment, it has been described that each of the first gas distribution module 330a, the second gas distribution module 130b, the third gas distribution module 330c, and the fourth gas distribution module 130d simultaneously distributes the first gas G1 and the plasmatic second gas PG2, but by operating each of the first gas distribution module 330a, the second gas distribution module 130b, the third gas distribution module 330c, and the fourth gas distribution module 130d according to an operation sequence based on control by a control module (not shown) and illustrated in FIGS. 4B and 5A to 5D, the above-described first gas G1 and plasmatic second gas PG2 may be spatially separated from each other and may be distributed to the first to fourth gas distribution areas without being limited thereto.

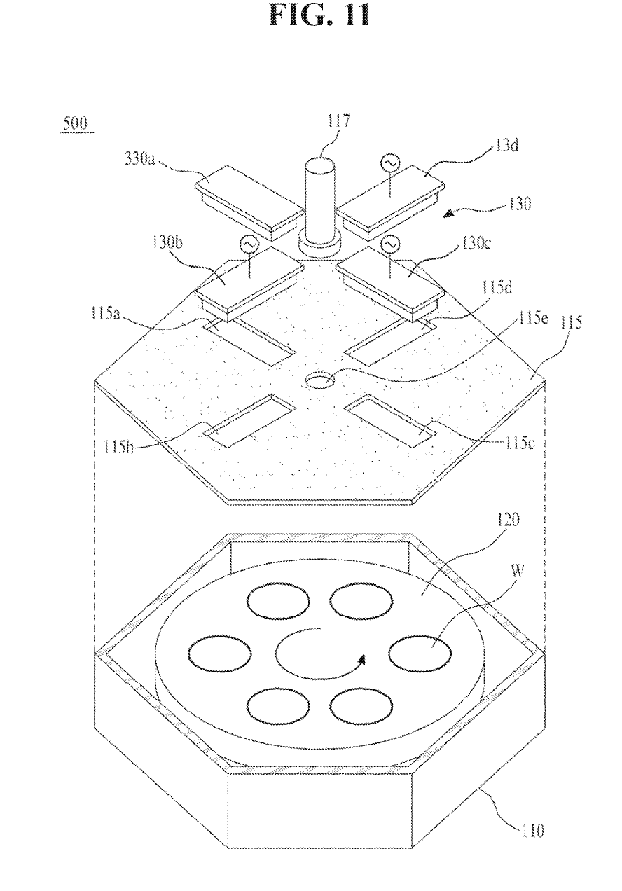

FIG. 11 is a diagram schematically illustrating a substrate treatment device according to a third embodiment of the present invention.

Referring to FIG. 11, a substrate treatment device 500 according to the third embodiment of the present invention includes a process chamber 110, a chamber lid 115, a substrate supporting part 120, and a gas distribution unit 130. Except for the gas distribution unit 130, the elements of the substrate treatment device 500 are the same as those of the above-described substrate treatment device 100, and thus, the above descriptions are applied to the same elements.

The gas distribution unit 130 is inserted into and installed in each of first to fourth module installation parts 115a to 115d provided in the chamber lid 115. The gas distribution unit 130 spatially separates a first gas which does not become plasmatic and second and third gases which become plasmatic, and downward distributes the spatially separated first to third gases toward the substrate supporting part 120. To this end, the gas distribution unit 130 includes a first gas distribution module 330a, a second gas distribution module 130b, a third gas distribution module 330c, and a fourth gas distribution module 130d.

The first gas distribution module 330a is inserted into and installed in the second module installation part 115b overlapping the above-described first gas distribution area and downward distributes the first gas, supplied from the gas supply means, to the first gas distribution area as-is without being plasmatic. To this end, as illustrated in FIG. 9, the first gas distribution module 330a includes a ground frame 410, a ground partition wall member 420, and a plurality of gas supply holes 430. Thus, the descriptions made with reference to FIG. 9 are applied to the elements.

The second gas distribution module 130b is inserted into and installed in the second module installation part 115b overlapping the above-described second gas distribution area, and downward distributes the above-described plasmatic third gas to the second gas distribution area. To this end, as illustrated in FIG. 3, the second gas distribution module 130b includes a ground frame 210, a ground partition wall member 220, a plurality of insulation members 230, and a plurality of plasma electrode members 240, and the above-described descriptions are applied to the elements. The second gas distribution module 130b is electrically connected to the plasma power supply unit 140 through a feeder cable to generate plasma in the gas distribution space 212 according to the plasma power supplied from the plasma power supply unit 140, makes the third gas supplied to the gas distribution space 212 plasmatic, and downward distributes the plasmatic third gas to the second gas distribution area.

The third gas distribution module 130c is inserted into and installed in the third module installation part 115c overlapping the above-described third gas distribution area, and downward distributes the above-described plasmatic second gas to the third gas distribution area. To this end, as illustrated in FIG. 3, the third gas distribution module 130c includes a ground frame 210, a ground partition wall member 220, a plurality of insulation members 230, and a plurality of plasma electrode members 240, and the above-described descriptions are applied to the elements. The third gas distribution module 130c is electrically connected to the plasma power supply unit 140 through a feeder cable to generate plasma in the gas distribution space 212 according to the plasma power supplied from the plasma power supply unit 140, makes the second gas supplied to the gas distribution space 212 plasmatic, and downward distributes the plasmatic second gas to the third gas distribution area.

The fourth gas distribution module 130d is inserted into and installed in the fourth module installation part 115d overlapping the above-described fourth gas distribution area, and downward distributes the plasmatic third gas to the fourth gas distribution area. To this end, as illustrated in FIG. 3, the fourth gas distribution module 130d includes a ground frame 210, a ground partition wall member 220, a plurality of insulation members 230, and a plurality of plasma electrode members 240, and the above-described descriptions are applied to the elements. By using such elements, the fourth gas distribution module 130d is electrically connected to the plasma power supply unit 140 through a feeder cable to generate plasma in the gas distribution space 212 according to the plasma power supplied from the plasma power supply unit 140, makes the third gas supplied to the gas distribution space 212 plasmatic, and downward distributes the plasmatic second gas to the fourth gas distribution area.

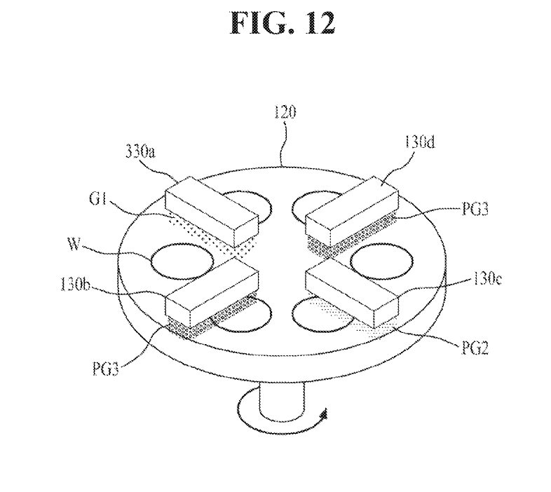

FIG. 12 is a diagram for describing a substrate treatment method using the above-described substrate treatment device according to the third embodiment of the present invention.

A substrate treatment method using the substrate treatment device according to the third embodiment of the present invention will be described with reference to FIG. 12.

First, a plurality of substrates W are loaded onto the substrate supporting part 120 at certain intervals.

Subsequently, the substrate supporting part 120 onto which the plurality of substrates W are loaded rotates in a certain direction.

Subsequently, the first gas is supplied to the first gas distribution module 330a, thereby downward distributing a first gas G1 to the first gas distribution area. Simultaneously, the second gas and the plasma power are supplied to the third gas distribution module 130c, thereby downward distributing a plasmatic second gas PG2 to the third gas distribution area. At this time, the first gas G1 and the plasmatic second gas PG2 are continuously distributed irrespective of a process cycle where the substrate supporting part 120 rotates in a certain direction once.

Simultaneously with that the first gas G1 and the plasmatic second gas PG2 are simultaneously distributed, the third gas and the plasma power are supplied to the second and fourth gas distribution modules 130b and 130d, thereby continuously downward distributing a plasmatic third gas PG3 to the second and fourth gas distribution areas. At this time, the plasmatic third gas PG3 is continuously distributed irrespective of the process cycle.

Therefore, each of the plurality of substrates W disposed on the substrate supporting part 120 passes through the first to fourth gas distribution areas according to a rotation of the substrate supporting part 120, and thus, a thin film material is deposited on each of the plurality of substrates W by reaction between the first gas G1 and the plasmatic second gas PG2 which are spatially separated from each other and are distributed from each of the first gas distribution module 330a, the second gas distribution module 130b, the third gas distribution module 130c, and the fourth gas distribution module 130d. At this time, the plasmatic third gas PG3 prevents the first gas G1 and the plasmatic second gases PG2 from being mixed and reacting with each other in the middle of being distributed to the substrate W and allows the first gas G1 and the plasmatic second gases PG2 to be distributed to a top of the substrate W, mixed, and react.

In the substrate treatment method using the substrate treatment device according to the third embodiment of the present invention, by operating each of the first gas distribution module 330a, the second gas distribution module 130b, the third gas distribution module 130c, and the fourth gas distribution module 130d according to an operation sequence illustrated in FIGS. 4B, 5A to 5D and 7, the above-described first gas G1 and plasmatic second and third gases PG2 and PG3 may be spatially separated from each other and may be distributed to the first to fourth gas distribution areas.

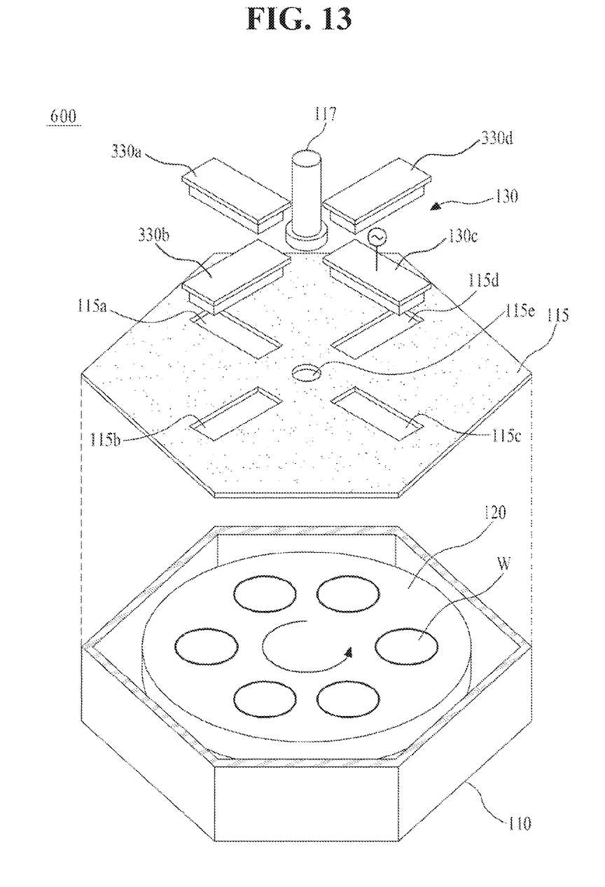

FIG. 13 is a diagram schematically illustrating a substrate treatment device according to a fourth embodiment of the present invention.

Referring to FIG. 13, a substrate treatment device 600 according to the fourth embodiment of the present invention includes a process chamber 110, a chamber lid 115, a substrate supporting part 120, and a gas distribution unit 130. Except for the gas distribution unit 130, the elements of the substrate treatment device 600 are the same as those of the above-described substrate treatment device 100, and thus, the above descriptions are applied to the same elements.

The gas distribution unit 130 is inserted into and installed in each of first to fourth module installation parts 115a to 115d provided in the chamber lid 115. The gas distribution unit 130 spatially separates a first gas which does not become plasmatic and second and third gases which become plasmatic, and downward distributes the spatially separated first to third gases toward the substrate supporting part 120. To this end, the gas distribution unit 130 includes a first gas distribution module 330a, a second gas distribution module 130b, a third gas distribution module 330c, and a fourth gas distribution module 130d.

The first gas distribution module 330a is inserted into and installed in the second module installation part 115b overlapping the above-described first gas distribution area and downward distributes the first gas, supplied from the gas supply means, to the first gas distribution area as-is without being plasmatic. To this end, as illustrated in FIG. 9, the first gas distribution module 330a includes a ground frame 410, a ground partition wall member 420, and a plurality of gas supply holes 430. Thus, the descriptions made with reference to FIG. 9 are applied to the elements.

The second gas distribution module 330b is inserted into and installed in the second module installation part 115b overlapping the above-described second gas distribution area and downward distributes the second gas, supplied from the gas supply means, to the second gas distribution area as-is without being plasmatic. To this end, as illustrated in FIG. 9, the second gas distribution module 330b includes a ground frame 410, a ground partition wall member 420, and a plurality of gas supply holes 430. Thus, the descriptions made with reference to FIG. 9 are applied to the elements.

The third gas distribution module 130c is inserted into and installed in the third module installation part 115c overlapping the above-described third gas distribution area, and downward distributes the above-described plasmatic second gas to the third gas distribution area. To this end, as illustrated in FIG. 3, the third gas distribution module 130c includes a ground frame 210, a ground partition wall member 220, a plurality of insulation members 230, and a plurality of plasma electrode members 240, and the above-described descriptions are applied to the elements. The third gas distribution module 130c is electrically connected to the plasma power supply unit 140 through a feeder cable to generate plasma in the gas distribution space 212 according to the plasma power supplied from the plasma power supply unit 140, makes the second gas supplied to the gas distribution space 212 plasmatic, and downward distributes the plasmatic second gas to the third gas distribution area.

The fourth gas distribution module 330d is inserted into and installed in the fourth module installation part 115d overlapping the above-described fourth gas distribution area and downward distributes the third gas, supplied from the gas supply means, to the fourth gas distribution area as-is without being plasmatic. To this end, as illustrated in FIG. 9, the fourth gas distribution module 330d includes a ground frame 410, a ground partition wall member 420, and a plurality of gas supply holes 430. Thus, the descriptions made with reference to FIG. 9 are applied to the elements.

FIG. 14 is a diagram for describing a substrate treatment method using the above-described substrate treatment device according to the fourth embodiment of the present invention.

A substrate treatment method using the substrate treatment device according to the fourth embodiment of the present invention will be described with reference to FIG. 14.

First, a plurality of substrates W are loaded onto the substrate supporting part 120 at certain intervals.

Subsequently, the substrate supporting part 120 onto which the plurality of substrates W are loaded rotates in a certain direction.

Subsequently, the first gas is supplied to the first gas distribution module 330a, thereby downward distributing a first gas G1 to the first gas distribution area. Simultaneously, the second gas and the plasma power are supplied to the third gas distribution module 130c, thereby downward distributing a plasmatic second gas PG2 to the third gas distribution area. At this time, the first gas G1 and the plasmatic second gas PG2 are continuously distributed irrespective of a process cycle where the substrate supporting part 120 rotates in a certain direction once.

Simultaneously with that the first gas G1 and the plasmatic second gas PG2 are simultaneously distributed, the third gas is supplied to the second and fourth gas distribution modules 330b and 330d, thereby continuously downward distributing a third gas G3, which does not become plasmatic, to the second and fourth gas distribution areas. At this time, the third gas G3 is continuously distributed irrespective of the process cycle.

Therefore, each of the plurality of substrates W disposed on the substrate supporting part 120 passes through the first to fourth gas distribution areas according to a rotation of the substrate supporting part 120, and thus, a thin film material is deposited on each of the plurality of substrates W by reaction between the first gas G1 and the plasmatic second gas PG2 which are spatially separated from each other and are distributed from each of the first gas distribution module 330a, the second gas distribution module 330b, the third gas distribution module 130c, and the fourth gas distribution module 330d. At this time, the third gas G3 prevents the first gas G1 and the plasmatic second gases PG2 from being mixed and reacting with each other in the middle of being distributed to the substrate W and allows the first gas G1 and the plasmatic second gases PG2 to be distributed to a top of the substrate W, mixed, and react.

In the substrate treatment method using the substrate treatment device according to the fourth embodiment of the present invention, by operating each of the first gas distribution module 330a, the second gas distribution module 330b, the third gas distribution module 130c, and the fourth gas distribution module 330d according to an operation sequence illustrated in FIGS. 4B, 5A to 5D and 7, the above-described first and third gases G1 and G3 and plasmatic second gas PG2 may be spatially separated from each other and may be distributed to the first to fourth gas distribution areas.

Those skilled in the art can understand that the present invention can be embodied in another detailed form without changing the technical spirit or the essential features. Therefore, it should be understood that the embodiments described above are exemplary from every aspect and are not restrictive. It should be construed that the scope of the present invention is defined by the below-described claims instead of the detailed description, and the meanings and scope of the claims and all variations or modified forms inferred from their equivalent concepts are included in the scope of the present invention.

1. A substrate treatment device comprising:
a process chamber;
a substrate supporting part installed in the process chamber to support a plurality of substrates, the substrate supporting part rotating in a certain direction;
a chamber lid covering a top of the process chamber to be opposite to the substrate supporting part; and
a gas distribution unit installed in the chamber lid to spatially separate different first and second gases and distribute the spatially separated first and second gases to the plurality of substrates,
wherein
the substrate supporting part comprises:
a first disk provided to be rotatable; and
at least one second disk disposed on the first disk to rotate and revolve about a center of the first disk according to the first disk rotating, the plurality of substrates being disposed on the at least one second disk, and
a rotation speed of the first disk differs from a rotation speed of the second disk.

2. The substrate treatment device of claim 1, wherein a ratio of the rotation speed of the first disk to the rotation speed of the second disk is 1:0.1 or more and 1:less than 1.

3. The substrate treatment device of claim 1, wherein the gas distribution unit comprises:
a first gas distribution module installed in the chamber lid to distribute the first gas supplied to a gas distribution space provided between a plurality of ground electrode members; and
a second gas distribution module installed in the chamber lid and separated from the first gas distribution module, the second gas distribution module distributing the second gas supplied to the gas distribution space provided between the plurality of ground electrode members.

4. The substrate treatment device of claim 3, wherein at least one of the first and second gas distribution modules comprises a plasma electrode member disposed between the plurality of ground electrode members to generate plasma in the gas distribution space.

5. A substrate treatment device comprising:
a process chamber;
a substrate supporting part installed in the process chamber to support a plurality of substrates, the substrate supporting part rotating in a certain direction;
a chamber lid covering a top of the process chamber to be opposite to the substrate supporting part; and
a gas distribution unit including a first gas distribution module installed in the chamber lid to overlap a first gas distribution area on the substrate supporting part, the first gas distribution module distributing a first gas to the first gas distribution area, and a second gas distribution module installed in the chamber lid to overlap a second gas distribution area spatially separated from the first gas distribution area, the second gas distribution module distributing a second gas to the second gas distribution area,
wherein
the substrate supporting part comprises:
a first disk provided to be rotatable; and
at least one second disk disposed on the first disk to rotate and revolve about a center of the first disk according to the first disk rotating, the plurality of substrates being disposed on the at least one second disk, and
the second gas distribution module makes the second gas plasmatic to distribute a plasmatic second gas according to a plasma power supplied to a plasma electrode member which is disposed alternately with a plurality of ground electrode members.

6. The substrate treatment device of claim 5, wherein the first gas distribution module distributes the first gas supplied to between the plurality of ground electrode members as-is, or makes the first gas plasmatic to distribute a plasmatic first gas according to the plasma power supplied to the plasma electrode member which is disposed alternately with the plurality of ground electrode members.

7. The substrate treatment device of claim 6, wherein each of the first and second gas distribution modules is provided in plurality, and each of the plurality of second gas distribution modules is disposed alternately with the plurality of first gas distribution modules.

8. The substrate treatment device of claim 5, wherein the gas distribution unit further comprises third and fourth gas distribution modules installed in the chamber lid and disposed between the first and second gas distribution modules to distribute a third gas to the plurality of substrates.

9. (canceled)

10. A substrate treatment method comprising:
(A) arranging a plurality of substrates at certain intervals on a substrate supporting part installed in a process chamber;
(B) rotating the substrate supporting part, on which the plurality of substrates are disposed, to rotate and revolve a second disk about a center axis of a first disk according to the first disk rotating; and
(C) spatially separating different first and second gases and distributing the spatially separated first and second gases to the plurality of substrates by using each of first and second gas distribution modules which are arranged at certain intervals in a chamber lid covering a top of the process chamber to be opposite to the substrate supporting part,
wherein in step (C),
the first gas distribution module distributes the first gas, supplied to a gas distribution space between a plurality of ground electrode members, to the plurality of substrates, and
the second gas distribution module distributing the second gas, supplied to the gas distribution space between the plurality of ground electrode members, to the plurality of substrates to be spatially separated from the first gas.

11. The substrate treatment method of claim 10, wherein a ratio of a rotation speed of the first disk to a rotation speed of the second disk is 1:0.1 or more and 1:less than 1.

12. The substrate treatment method of claim 11, wherein step (C) simultaneously or sequentially performs a first gas distribution operation of distributing the first gas through the first gas distribution module and a second gas distribution operation of distributing the second gas through the second gas distribution module.

13. The substrate treatment method of claim 10, wherein the first gas is changed to a plasmatic first gas by plasma generated in a gas distribution space of the first gas distribution module, and the plasmatic first gas is distributed to the plurality of substrates.
